(19) United States
(12) Patent Application Publication
(10) Pub. No.: US 2025/0112625 A1
(43) Pub. Date: Apr. 3, 2025

(54) CLOCK ERROR DETECTION CIRCUIT

(71) Applicant: LAPIS Technology Co., Ltd., Yokohama (JP)

(72) Inventor: Masato YAMAZAKI, Kouhoku-ku (JP)

(73) Assignee: LAPIS Technology Co., Ltd., Yokohama (JP)

(21) Appl. No.: 18/898,481

(22) Filed: Sep. 26, 2024

(30) Foreign Application Priority Data
Sep. 29, 2023 (JP) 2023-169915

(51) Int. Cl. H03K 5/135; H03K 19/21; H03K 21/08

(52) U.S. Cl. CPC H03K 5/135; H03K 19/21; H03K 21/08

(57) ABSTRACT

A clock error detection circuit which includes a cycle signal generation circuit that generates a cycle signal that reverses a level thereof at a start of each one cycle of a subject clock signal, a delay circuit that delays the cycle signal by a time shorter or a time longer than a prescribed cycle for the subject clock signal to output a delayed signal of the cycle signal, a holding circuit that holds a level of the delayed signal at the start of each one cycle of the subject clock signal to generate a hold signal, and a determination circuit that determines whether the level of the cycle signal matches the level of the hold signal to generate a result of the determination.

### CROSS-REFERENCE TO RELATED APPLICATION

This application is based upon and claims the benefit of priority from the prior Japanese Patent Application No. 2023-169915 filed on Sep. 29, 2023, the entire contents of which are incorporated herein by reference.

### BACKGROUND

### 1. Technical Field

This disclosure relates to a clock error detection circuit for detecting an error in cycle length of a clock signal.

### 2. Description of the Related Art

In general, electronic circuits are often operated in synchronization with an input clock signal, and in the event of an error where a cycle of the clock signal is shorter than a prescribed cycle even in one cycle, it is not possible to guarantee the circuit operation. Similarly, in the event of an error where the cycle is longer than the prescribed cycle, it is assumed that the required operation performance of the circuit is not met.

For example, a clock error detection circuit that detects an error in a cycle of a clock signal is disclosed in Japanese Patent Kokai No. H10 (1998)-240374.

The clock error detection circuit disclosed in Japanese Patent Kokai No. H10 (1998)-240374 includes a delay circuit that delays a subject clock signal by one cycle, a comparison circuit that compares the subject clock signal with a delayed clock signal obtained from the delay circuit, and a counter that measures the duration of a high level output state of the comparison circuit. When the subject clock signal and the delayed clock signal match, an output signal of the comparison circuit becomes at the low level, and the subject clock signal is determined to be in a normal state. On the other hand, when the subject clock signal and the delayed clock signal do not match, the output signal of the comparison circuit becomes at the high level. A duration of the high level output state of the comparison circuit is measured by the counter. When the duration of the high level exceeds a pre-set cycle error detection duration, an error detection signal is generated by the counter, and the subject clock signal is determined to be in an error state.

In such a conventional clock error detection circuit, a high-speed clock signal is supplied to the counter separately from the subject clock signal in order to measure the duration of the high level output state of the comparison circuit by the counter. The counter measures the duration of the high level output state of the comparison circuit by counting pulses of the high-speed clock signal.

However, in the conventional clock error detection circuit, there is a problem that a circuit configuration would become complex because it is necessary to prepare the high-speed clock signal and also to have the counter to count the pulses of the high-speed clock signal. In addition, since it is necessary to consider an accuracy of the high-speed clock signal, it is necessary to determine in advance an allowable range for the detection duration of an error in cycle length of the subject clock signal.

It is an object of the disclosure to provide a clock error detection circuit that can detect an error in cycle length of the subject clock signal with a high detection accuracy using a simple configuration.

### SUMMARY

A clock error detection circuit according to the disclosure is a clock error detection circuit for detecting an error in cycle length of a subject clock signal, comprising: a cycle signal generation circuit that generates a cycle signal that reverses a level thereof at a start of each one cycle of the subject clock signal; a delay circuit that delays the cycle signal by a time shorter or a time longer than a prescribed cycle for the subject clock signal to output a delayed signal of the cycle signal; a holding circuit that holds a level of the delayed signal at the start of each one cycle of the subject clock signal to generate a hold signal; and a determination circuit that determines whether the level of the cycle signal matches the level of the hold signal to generate a result of the determination.

A clock error detection circuit according to the disclosure is a clock error detection circuit for detecting an error in cycle length of a subject clock signal, comprising: a cycle signal generation circuit that generates a cycle signal that reverses a level thereof at a start of each one cycle of the subject clock signal; a first delay circuit that delays the cycle signal by a time shorter than a prescribed cycle for the subject clock signal to output a first delayed signal of the cycle signal; a second delay circuit that delays the cycle signal by a time longer than a prescribed cycle for the subject clock signal to output a second delayed signal of the cycle signal; a holding circuit that at the start of each one cycle of the subject clock signal, holds a level of the first delayed signal to generate a first hold signal and holds a level of the second delayed signal to generate a second hold signal; a first determination circuit that determines whether the level of the cycle signal matches the level of the first hold signal to generate a result of the determination; and a second determination circuit that determines whether the level of the cycle signal matches the level of the second hold signal to generate a result of the determination.

### BRIEF DESCRIPTION OF THE DRAWINGS

FIG. 1 is a circuit diagram of a clock error detection circuit 10 of Embodiment 1 of the disclosure;

FIG. 2 is a time chart illustrating a signal waveform of each part of the clock error detection circuit 10 when a subject clock signal is in a normal state;

FIG. 3 is a time chart illustrating a signal waveform of each part of the clock error detection circuit 10 when the subject clock signal is in an error state;

FIG. 4 is a circuit diagram of a clock error detection circuit 40 of Embodiment 2 of the disclosure;

FIG. 5 is a time chart illustrating a signal waveform of each part of the clock error detection circuit 40 when the subject clock signal is in a normal state;

FIG. 6 is a time chart illustrating a signal waveform of each part of the clock error detection circuit 40 when the subject clock signal is in an error state; and

FIG. 7 is a circuit diagram illustrating a clock error detection circuit 10 of an example of a modification.

### DETAILED DESCRIPTION

In the clock error detection circuit of the disclosure, the cycle signal that reverses the level thereof at the start of each one cycle of the subject clock signal is delayed by the delay circuit by the time shorter or the time longer than the one prescribed cycle of the subject clock signal to generate the delayed signal, the hold signal is generated by holding the level of the delayed signal at the start of each one time cycle of the subject clock signal, and the determination circuit determines whether the level of the hold signal matches the level of the cycle signal. Therefore, it is possible to detect a cycle error in the subject clock signal with a simple configuration and with a high accuracy.

The following is a detailed description of each embodiment of the disclosure with reference to the drawings.

### Embodiment 1

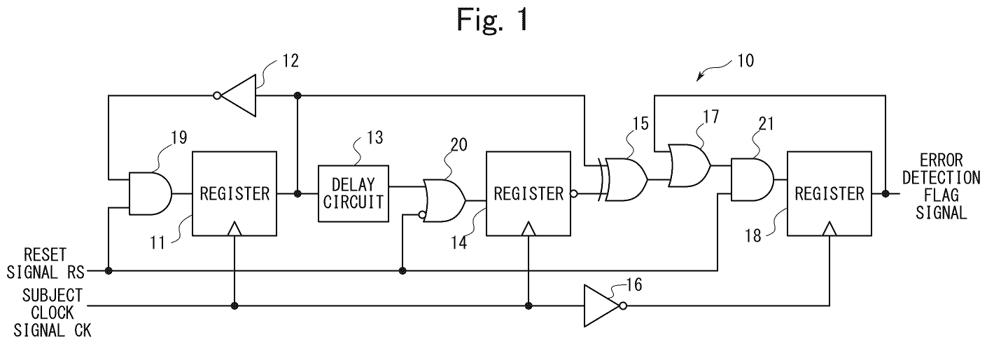

FIG. 1 illustrates a circuit diagram of a clock error detection circuit 10 of Embodiment 1. This clock error detection circuit 10 includes three registers 11, 14, 18, inverters 12, 16, a delay circuit 13, an XOR circuit 15, OR circuits 17, 20, and AND circuits 19, 21. The clock error detection circuit 10 receives a subject clock signal CK and a reset signal RS. The clock error detection circuit 10 detects a short cycle error in which an actual cycle of the subject clock signal CK becomes shorter than a cycle (prescribed cycle TCK) prescribed in advance for the subject clock signal CK.

The register 11, the inverter 12, and the AND circuit 19 constitute a frequency dividing circuit (cycle signal generation circuit) that divides the subject clock signal CK by two. The reset signal RS is supplied to one of two input terminals of the AND circuit 19. An output terminal of the inverter 12 is connected to the other input terminal of the AND circuit 19. An output terminal of the AND circuit 19 is connected to an input terminal of the register 11. The register 11 includes a clock terminal and an output terminal in addition to the input terminal. The clock terminal of the register 11 is supplied with the subject clock signal CK, and the output terminal is connected to an input terminal of the inverter 12. The register 11 holds a signal level of the input terminal in response to a rise of the subject clock signal CK supplied to the clock terminal and outputs a hold signal having the held level from the output terminal. The inverter 12 inverts a level of the output terminal of the register 11 and outputs a signal having the inverted level. The AND circuit 19 takes a logical product of the level of the reset signal RS and the output signal level of the inverter 12.

The delay circuit 13 delays its input signal by a delay time (slightly shorter than the prescribed cycle TCK) that is slightly shorter than the prescribed cycle TCK of the subject clock signal CK. An input terminal of the delay circuit 13 is connected to the output terminal of the register 11 and receives the hold signal of the register 11 as an input signal. An output terminal of the delay circuit 13 is connected to one input terminal of two input terminals of the OR circuit 20. The other input terminal of the OR circuit 20 is an inverted input terminal, and the reset signal RS is supplied to the inverted input terminal. The output terminal of the OR circuit 20 is connected to the input terminal of the register 14. The register 14 has a clock terminal and an inverted output terminal in addition to the input terminal. The clock terminal of the register 14 is supplied with the subject clock signal CK, and the inverted output terminal is connected to one input terminal of the two input terminals of the XOR circuit 15. The register 14 holds a signal level at the input terminal in response to the rise of the subject clock signal CK supplied to the clock terminal, and outputs the inverted level of the held signal level from the output terminal.

The other input terminal of the XOR circuit 15 is connected to the output terminal of the register 11. The XOR circuit 15 corresponds to a determination circuit and takes an exclusive OR of output signal levels of the registers 11 and 14. As will be described later, when an output signal level of the XOR circuit 15 changes from a low level (L) to a high level (H), it means that the short cycle error has been detected in the subject clock signal CK.

The inverter 16, the OR circuit 17, the register 18, and the AND circuit 21 constitute a holding circuit that holds the high level output of the XOR circuit 15. One input terminal of two input terminals of the OR circuit 17 is connected to an output terminal of the XOR circuit 15, and the other input terminal is connected to an output terminal of the register 18. In addition, an output terminal of the OR circuit 17 is connected to one input terminal of two input terminals of the AND circuit 21. The reset signal RS is supplied to the other input terminal of the AND circuit 21. An output terminal of the AND circuit 21 is connected to an input terminal of the register 18. The register 18 includes a clock terminal in addition to the input terminal and the output terminal. The clock terminal of the register 18 is supplied with the subject clock signal CK via the inverter 16, and the output terminal is connected to the other input terminal of the OR circuit 17 as described above. The register 18 holds a signal level of the input terminal in response to a rise of the inverted signal of the subject clock signal CK supplied to the clock terminal and outputs it from the output terminal. An error detection flag signal is output from the output terminal of the register 18, and when the error detection flag signal having a high level is output, it indicates that the short cycle error in the subject clock signal CK has been detected.

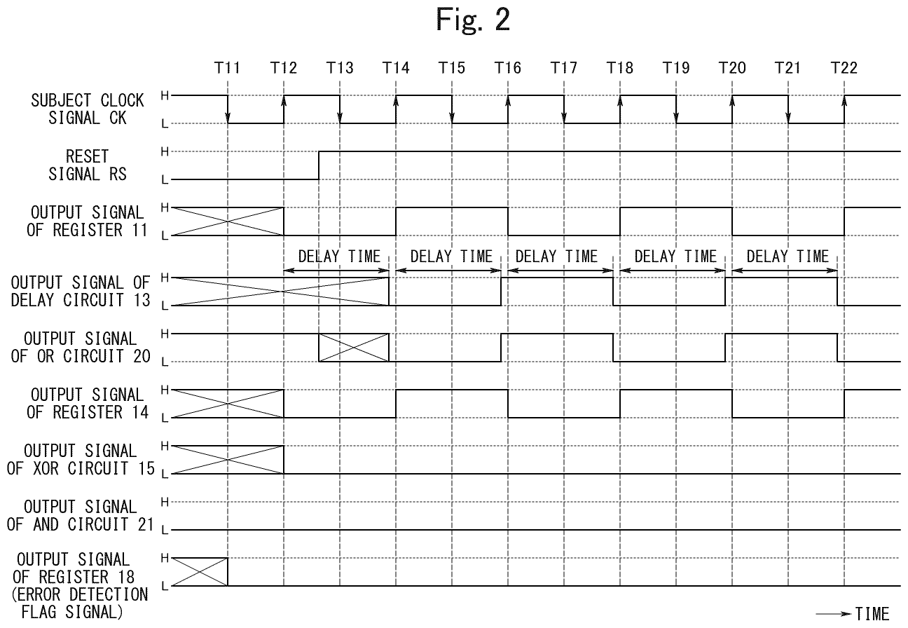

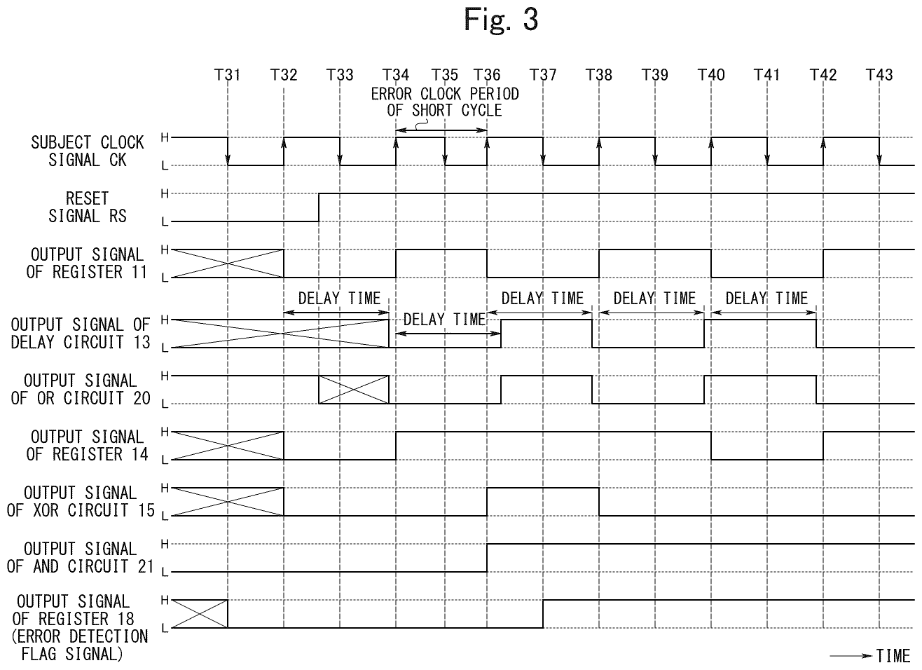

Next, an operation of the clock error detection circuit 10, which has the structure described above, is described using the time charts in FIGS. 2 and 3.

The subject clock signal CK illustrated in FIGS. 2 and 3 has a prescribed cycle TCK during a normal operation, and is assumed to repeat the low level and a high level with a duty ratio of 50%. The duty ratio of the subject clock signal CK may be other than 50%. In this Embodiment 1, a rising timing of the subject clock signal CK is used as a start time point of one cycle of the subject clock signal CK. However, it is also possible to use another timing as the start point. In the example of the subject clock signal CK illustrated in FIG. 2, the cycle is always the prescribed cycle TCK, which is normal. In the example of the subject clock signal CK illustrated in FIG. 3, the cycle temporarily becomes shorter than the prescribed cycle TCK, and a short cycle error occurs.

First, in the subject clock signal CK illustrated in FIG. 2, there are time points T11 to T22. The odd-numbered time points T11, T13, and so on of the time points T11 to T22 are falling timings, and the even-numbered time points T12, T14, and so on of the time points T11 to T22 are rising timings. The subject clock signal CK is at a low level at the time point T11, the subject clock signal CK is at a high level at the time point T12, and a set of the low level and the high level repeats at following the time points T13 to T22.

The register 11 holds and outputs the levels of the input terminal (the output signal levels of the AND circuit 19) at the rise of the time points T12, T14, and so on of the subject clock signal CK. The register 14 holds the levels of the input terminal (the output signal levels of the OR circuit 20) at the rise of the time points T12, T14, and so on of the subject clock signal CK and outputs the inverted level of the held signal level. The register 18 holds and outputs the levels of the input terminal (the output signal levels of the AND circuit 21) at the fall of the time points T11, T13, and so on of the subject clock signal CK.

As illustrated in FIG. 2, when the reset signal RS changes from the low level to the high level between the time points T12 and T13, the output signal level of the AND circuit 21 becomes at the low level because the reset signal RS is at the low level at an earlier time point T11, and the output signal level of the register 18 becomes at the low level at the time point T11. The error detection flag signal, which is the low level output signal of the register 18, indicates that the subject clock signal CK is normal.

At the time point T12, the reset signal RS is at the low level. Thus, the output signal of the AND circuit 19 is at the low level. This low level causes the output signal of the register 11 to become at the low level at the time point T12. Also, since the output signal of the OR circuit 20 is high at the time point T12, this high level causes the output signal of the register 14 to become at the low level. Up to the time point T12, the clock error detection circuit 10 is in a reset state.

At the time point T13, the reset signal RS is at the high level. Thus, the clock error detection circuit 10, which was in the reset state, starts a clock error detection operation, and an exclusive OR of the low level output signal of the register 11 and the low level output signal of the register 14 is taken by the XOR circuit 15. Since the XOR circuit 15 generates the output signal having the low level and the low level output signal is supplied from the OR circuit 17 to the AND circuit 21, the output signal of the AND circuit 21 is maintained at the low level. The error detection flag signal, which is the output signal of the register 18, is maintained at the low level at the time point T13, indicating that the subject clock signal CK is normal. In other words, the error detection flag signal having the high level is not generated.

At the rising timing of the subject clock signal CK after the time point T14, the level held until then in the register 11 is inverted by the inverter 12, and the inverted level is held and output by the register 11 at the next rising timing. The output signal of the register 11 switches between the high level and the low level at each rising timing of the subject clock signal CK. As a result, the output signal of the register 11 has a cycle that is twice the cycle of the subject clock signal CK.

At the time point T14, the output signal of the register 11 is delayed by the delay circuit 13 for a time of slightly shorter than the one prescribed cycle TCK of the subject clock signal CK, and the delayed signal is input to the input terminal of the register 14 via the OR circuit 20. Since the delay time of the delay circuit 13 is the time of slightly shorter than the one prescribed cycle TCK of the subject clock signal CK, the low level output signal of the OR circuit 20 is held in the register 14 at the time point T14. However, the high level is output from the register 14 by inversion output.

At the time point T15, unlike at the time point T13, the high level output signal from the register 11 and the high level output signal from the register 14 are input into the XOR circuit 15. However, the XOR circuit 15 continues to generate the output signal having the low level without change. Thus, the low level output signal is supplied from the OR circuit 17 to the AND circuit 21 similarly to the time point T13. Thus, the output signal of the AND circuit 21 is maintained at the low level. The error detection flag signal output from the register 18 continues to maintain at the low level at the time point T15, indicating that the subject clock signal CK is normal.

Even after the time point T15, the output signal levels of the registers 11 and 14 continue to be confirmed to be inverted at the rise of the subject clock signal CK (at the even-numbered time points), and the output signal levels of the registers 11 and 14 continue to be confirmed to be the same (the hold signal levels of the registers 11 and 14 are different from each other) at the fall of the subject clock signal CK (at the odd-numbered time points). In the example illustrated in FIG. 2, where the subject clock signal CK has no error cycle, the error detection flag signal output from the register 18 is always at the low level, indicating that the subject clock signal CK is normal.

Next, in the example of the subject clock signal CK illustrated in FIG. 3, which exhibits the short cycle error, there are time points T31 to T43. The odd-numbered time points T31, T33, and so on of the time points T31 to T43 are the falling timings, and the even-numbered time points T32, T34, and so on are the rising timings. The subject clock signal CK is at the low level at the time point T31 and the subject clock signal CK is at the high level at the time point T32, and this repeats at the time points T33 to T43.

The register 11 holds and outputs the levels of the input terminal (the output signal levels of the AND circuit 19) at the rises of the time points T32, T34, and so on of the subject clock signal CK. The register 14 holds the levels of the input terminal (the output signal levels of the OR circuit 20) at the rise of the time points T32, T34, and so on of the subject clock signal CK and outputs the inverted level of the held level. The register 18 holds and outputs the levels of the input terminal (the output signal levels of the AND circuit 21) at the fall of the time points T31, T33, and so on of the subject clock signal CK.

As illustrated in FIG. 3, when the reset signal RS changes from the low level to the high level between the time point T32 and the time point T33, the reset signal RS is at the low level at the time point T31 therebefore. Thus, the output signal level of the AND circuit 21 becomes at the low level, and the output signal level of the register 18 becomes at the low level at the time point T31. The error detection flag signal, which is the low level output signal of the register 18, indicates that the subject clock signal CK is normal.

At the time point T32, since the reset signal RS is at the low level, the output signal of the AND circuit 19 is at the low level. This low level causes the output signal of the register 11 to become at the low level at the time point T32. Also, since the output signal of the OR circuit 20 is at the high level at the time point T32, this high level causes the output signal of the register 14 to become at the low level.

At the time point T33, since the reset signal RS is at the high level, the clock error detection circuit 10, which was in the reset state, starts the clock error detection operation, and an exclusive OR of the low level output signal of the register 11 and the low level output signal of the register 14 is taken by the XOR circuit 15. Since the XOR circuit 15 generates the output signal having the low level, and the low level output signal is supplied from the OR circuit 17 to the AND circuit 21, the AND circuit 21 maintains the low level output signal. The error detection flag signal, which is the output signal of the register 18, is maintained at the low level at the time point T33, indicating that the subject clock signal CK is normal. In other words, the error detection flag signal having the high level is not generated.

At the rising timing of the subject clock signal CK after the time point T34, the level held until then in the register 11 is inverted by the inverter 12, and the inverted level is held and output by the register 11 at the next rising timing, and the output signal level of the register 11 switches between the high level and the low level at each rising timing of the subject clock signal CK.

At the time point T34, the output signal of the register 11 is delayed by the delay circuit 13 for the time of slightly shorter than the one prescribed cycle TCK of the subject clock signal CK, and the delayed signal is input to the input terminal of the register 14 via the OR circuit 20. Since the delay time of the delay circuit 13 is the time of slightly shorter than the one prescribed cycle TCK of the subject clock signal CK, the low level output signal of the OR circuit 20 is held in the register 14 at the time point T34. However, the high level is output from the register 14 by inversion output.

As illustrated in FIG. 3, the period from the time point T34 to the time point T36 is an error clock period of a short cycle in the subject clock signal CK, and it is shorter than the one prescribed cycle TCK in the period.

At the time point T35 in the short cycle error clock period, unlike at the time point T33, the high level output signal of the register 11 and the high level output signal of the register 14 are input to the XOR circuit 15. However, since the XOR circuit 15 continuously generate the low level output signal without change, the low level output signal is supplied from the OR circuit 17 to the AND circuit 21 similarly to the time point T33, and the AND circuit 21 maintains the low level output signal. The error detection flag signal, which is the output signal of the register 18, continues to be maintained at the low level at the time point T35, indicating that the subject clock signal CK is normal.

At the time point T36 when the short cycle error clock period ends, the low level output signal of the register 11 at the time point T34 is delayed by the delay circuit 13 for the time of slightly shorter than the one prescribed cycle TCK of the subject clock signal CK, and the delayed low level signal is input to the input terminal of the register 14 via the OR circuit 20. In other words, the delay time of the delay circuit 13 is the time of slightly shorter than the one prescribed cycle TCK of the subject clock signal CK. However, at the end of this short cycle error clock period T36, the output signal of the delay circuit 13 remains at the low level. Therefore, since the low level output signal of the OR circuit 20 is held in the register 14, the high level is continuously output from the inverted output of the register 14.

At the time point T36, an exclusive OR of the low level output signal of the register 11 and the high level output signal of the register 14 is taken by the XOR circuit 15. As illustrated in FIG. 3, since the XOR circuit 15 generates the high level output signal instead of the low level output signal, the high level output signal from the OR circuit 17 is supplied to the AND circuit 21. As a result, the output signal of the AND circuit 21 changes from the low level to the high level. Since this high level is held in the register 18 at the time point T37, the error detection flag signal, which is the output signal of the register 18, changes from the low level to the high level at the time point T37, indicating an error in the subject clock signal CK.

After the time point T36, the cycle of the subject clock signal CK returns to the prescribed cycle TCK and becomes normal. As a result, since the output signal level of the register 11 and the output signal level of the register 14 match after a time point T38, the output signal of the XOR circuit 15 returns to the low level. However, since the high level output signal of the register 18 is supplied to the AND circuit 21 via the OR circuit 17, the AND circuit 21 maintain the high level output signal. Thus, since the high level is held by the register 18 at the odd-numbered time points T39, T41, and so on, the error detection flag signal, which is the output signal of the register 18, maintains the high level, and indicates the error in the subject clock signal CK.

Accordingly, in the clock error detection circuit 10 of Embodiment 1, the cycle signal that reverses its level at each rising timing of the subject clock signal CK is generated by the frequency dividing circuit including the register 11, the delay circuit 13 delays the cycle signal by the time of slightly shorter than the one prescribed cycle TCK of the subject clock signal CK to generate the delayed signal, the level of the delayed signal is held in the register 14 at each rising timing of the subject clock signal CK to generate the hold signal, the XOR circuit 15 determines whether the level of the cycle signal matches the level of the hold signal, and when the XOR circuit 15 does not obtain a determination result of the match, the high level error detection flag signal indicating the error in the subject clock signal CK is generated. Thus, the short cycle error in which the cycle of the subject clock signal CK becomes shorter than the prescribed cycle TCK can be detected with a simple configuration and with a high detection accuracy.

### Embodiment 2

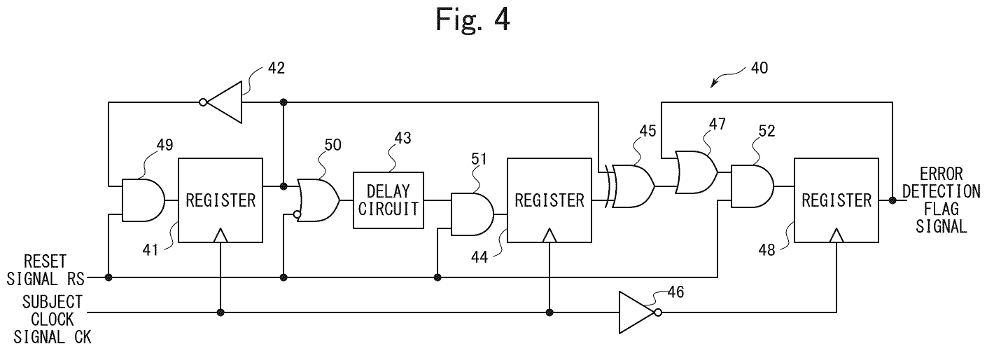

FIG. 4 illustrates a circuit diagram of a clock error detection circuit 40 of Embodiment 2. This clock error detection circuit 40 includes three registers 41, 44, and 48, inverters 42 and 46, a delay circuit 43, an XOR circuit 45, OR circuits 47 and 50, and AND circuits 49, 51, and 52. The clock error detection circuit 40 receives a subject clock signal CK and a reset signal RS. The clock error detection circuit 40 detects a long cycle error, in which an actual cycle of the subject clock signal CK becomes longer than a prescribed cycle TCK.

The register 41, the inverter 42, and the AND circuit 49 constitute a frequency dividing circuit that divides the subject clock signal CK by two. The reset signal RS is supplied to one input terminal of two input terminals of the AND circuit 49. An output terminal of the inverter 42 is connected to the other input terminal of the AND circuit 49. An output terminal of the AND circuit 49 is connected to an input terminal of the register 41. The register 41 includes a clock terminal and an output terminal in addition to the input terminal. The clock terminal of the register 41 is supplied with the subject clock signal CK, and the output terminal is connected to an input terminal of the inverter 42. The register 41 holds a signal level of the input terminal in response to a rise of the subject clock signal CK supplied to the clock terminal, and outputs it from the output terminal. The inverter 42 inverts a level of the output terminal of the register 41 and outputs a signal with the inverted level. The AND circuit 49 takes a logical product of the level of the reset signal RS and the output signal level of the inverter 42.

One of two input terminals of the OR circuit 50 is an inverted input terminal, and the reset signal RS is supplied to this inverted input terminal. The other input terminal of the OR circuit 50 is a non-inverted input terminal, and is connected to the output terminal of the register 41. An output terminal of the OR circuit 50 is connected to an input terminal of the delay circuit 43.

The delay circuit 43 delays its input signal by a delay time (slightly longer than the prescribed cycle TCK) that is slightly longer than the prescribed cycle TCK of the subject clock signal CK. An output terminal of the delay circuit 43 is connected to one input terminal of two input terminals of the AND circuit 51. The reset signal RS is supplied to the other input terminal of the AND circuit 51. An output terminal of the AND circuit 51 is connected to an input terminal of the register 44. The register 44 includes a clock terminal and an output terminal in addition to the input terminal. The clock terminal of the register 44 is supplied with the subject clock signal CK, and the output terminal is connected to one input terminal of two input terminals of the XOR circuit 45. The register 44 holds a signal level of the input terminal in response to the rise of the subject clock signal CK supplied to the clock terminal and outputs it from the output terminal.

The other input terminal of the XOR circuit 45 is connected to the output terminal of the register 41. The XOR circuit 45 corresponds to a determination circuit, and takes an exclusive OR of output signal levels of the registers 41, 44. As will be described later, when an output signal level of the XOR circuit 45 changes from a low level (L) to a high level (H), it means that the long cycle error in the subject clock signal CK has been detected.

The inverter 46, the OR circuit 47, the register 48, and the AND circuit 52 constitute a holding circuit that holds the high level output of the XOR circuit 45. One input terminal of two input terminals of the OR circuit 47 is connected to an output terminal of the XOR circuit 45, and the other input terminal is connected to an output terminal of the register 48. In addition, an output terminal of the OR circuit 47 is connected to one input terminal of two input terminals of the AND circuit 52. The reset signal RS is supplied to the other input terminal of the AND circuit 52. An output terminal of the AND circuit 52 is connected to an input terminal of the register 48. The register 48 includes a clock terminal in addition to the input terminal and the output terminal. The clock terminal of the register 48 is supplied with the subject clock signal CK via the inverter 46, and the output terminal is connected to the other input terminal of the OR circuit 47 as described above. The register 48 holds the signal level of the input terminal in response to a rise of the inverted signal of the subject clock signal CK supplied to the clock terminal and outputs it from the output terminal. The error detection flag signal is output from the output terminal of the register 48, and when the error detection flag signal having the high level is output, it indicates that the long cycle error in the subject clock signal CK has been detected.

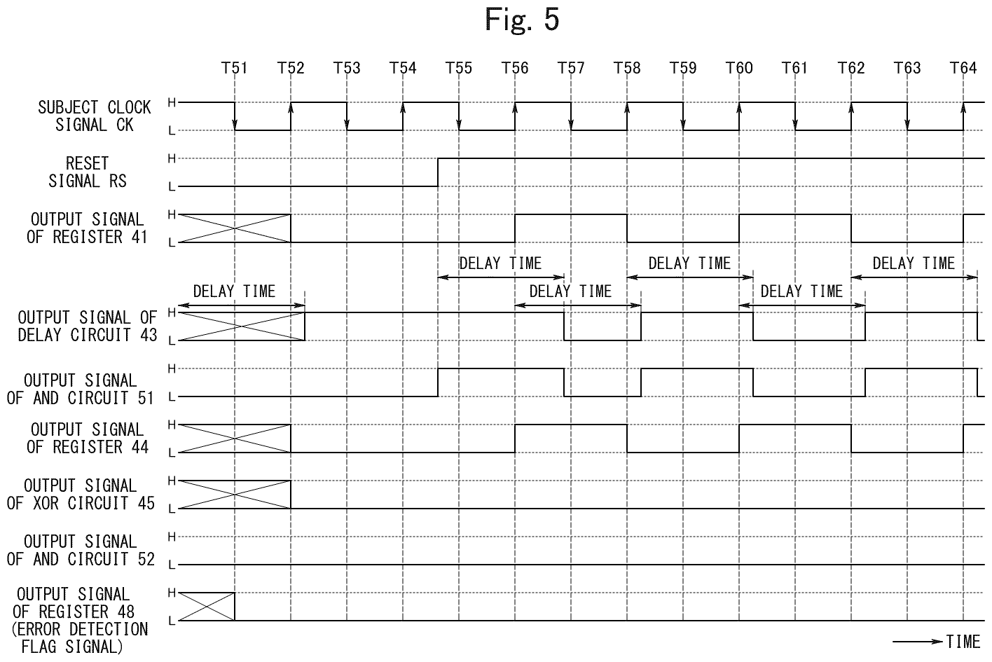

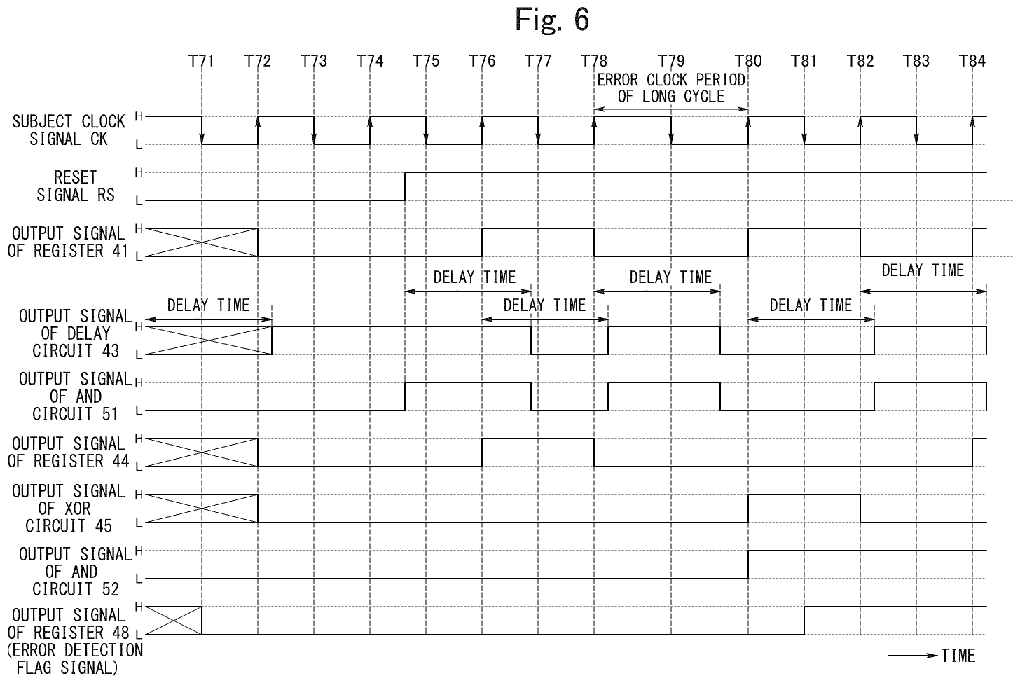

Next, an operation of the clock error detection circuit 40, which has the structure described above, will be described using the time charts in FIGS. 5 and 6.

The subject clock signal CK illustrated in FIGS. 5 and 6 has the prescribed cycle TCK during a normal operation, and repeats the low level and the high level with a duty ratio of 50%. The duty ratio of the subject clock signal CK can be other than 50%. Also in this Embodiment 2, a rising timing of the subject clock signal CK is used as a start time point of one cycle of the subject clock signal CK. However, it is also possible to use another timing as the start point. In the example of the subject clock signal CK illustrated in FIG. 5, the cycle is always the prescribed cycle TCK in the normal case. In the example of the subject clock signal CK illustrated in FIG. 6, a long cycle error occurs in which the cycle temporarily becomes longer than the prescribed cycle TCK.

First, in the subject clock signal CK illustrated in FIG. 5, there are time points T51 to T64. The odd-numbered time points T51, T53, and so on of the time points T51 to T64 are falling timings, and the even-numbered time points T52, T54, and so on are rising timings. The subject clock signal CK is at the low level at the time point T51, the subject clock signal CK is at the high level at the time point T52, and this repeats at the time points T53 to T64.

The register 41 holds and outputs the levels of the input terminal (the output signal levels of the AND circuit 49) at the rise of the subject clock signal CK at the time points T52, T54, and so on. The register 44 holds and outputs the levels of the input terminal (the output signal levels of the AND circuit 51) at the rise of the subject clock signal CK at the time points T52, T54, and so on. The register 48 holds and outputs the levels of the input terminal (the output signal level of the AND circuit 52) at the fall of the subject clock signal CK at the time points T51, T53, and so on.

As illustrated in FIG. 5, when the reset signal RS changes from the low level to the high level between the time points T54 and T55, the reset signal RS is at the low level at the time points T51, T52, and T53 therebefore. Thus, the output signal level of the AND circuit 52 become at the low level, and the output signal level of the register 48 become at the low level at the time point T51. The error detection flag signal, which is the low level output signal of the register 48, indicates that the subject clock signal CK is normal.

Since the reset signal RS is at the low level at the time point T52, the output signal of the AND circuit 49 is at the low level. This low level causes the output signal of the register 41 to become at the low level at the time point T52. Also, since the output signal of the AND circuit 51 is at the low level at the time point T52, this low level causes the output signal of the register 44 to become at the low level.

As mentioned above, since the reset signal RS is at the low level at the time point T53, the output signal level of the AND circuit 52 is at the low level similarly to the case of the time point T51, and the output signal level of the register 48 is at the low level at the time point T53. The error detection flag signal, which is the low level output signal of the register 48, indicates that the subject clock signal CK is normal.

Since the reset signal RS is at the low level at the time point T54, the output signal of the AND circuit 49 is at the low level similarly to the case of the time point T52. This low level causes the output signal of the register 41 to become at the low level at the time point T54. Also, since the output signal of the AND circuit 51 is the low level at the time point T54, this low level causes the output signal of the register 44 to become at the low level. Up to the time point T54, the clock error detection circuit 40 is in a reset state.

Since the reset signal RS becomes at the high level at the time point T55, the clock error detection circuit 40, which was in the reset state, starts a clock error detection operation, and the low level output signal level of the register 41 is supplied to the delay circuit 43 via the OR circuit 50. In addition, an exclusive OR of the low level output signal of the register 41 and the low level output signal of the register 44 is taken by the XOR circuit 45. Since the XOR circuit 45 generates the low level output signal, and the low level output signal from the OR circuit 47 is supplied to the AND circuit 52, the AND circuit 52 maintains the low level output signal. The error detection flag signal, which is the output signal of the register 48, is maintained at the low level at the time point T55, indicating that the subject clock signal CK is normal. In other words, the error detection flag signal having the high level is not generated.

At the rising timing of the subject clock signal CK after the time point T56, the level held until then in the register 41 is inverted by the inverter 42, and the inverted level is held and output by the register 41 at the next rising timing. The output signal of the register 41 switches between the high level and the low level at each rising timing of the subject clock signal CK. As a result, the output signal of the register 41 has a cycle that is twice the cycle of the subject clock signal CK.

At the time point T56, since the high level output signal of the register 41 is supplied to the delay circuit 43 via the OR circuit 50 without change, the high level output signal of the register 41 is delayed by the delay circuit 43 for a time of slightly longer than the one prescribed cycle TCK of the subject clock signal CK, and the delayed signal is input to the input terminal of the register 44 via the AND circuit 51. Since the delay time of the delay circuit 43 is the time of slightly longer than the one prescribed cycle TCK of the subject clock signal CK, the high level output signal of the AND circuit 51 is held and output to the register 44 at the time point T56.

At the time point T57, unlike at the time point T55, the high level output signal from the register 41 and the high level output signal from the register 44 are input into the XOR circuit 45. However, since the XOR circuit 45 generates the low level output signal without change, the low level output signal is supplied from the OR circuit 47 to the AND circuit 52 similarly to the time point T55. Thus, the AND circuit 52 maintains the low level output signal. The output signal of the register 48 is maintained at the low level at the time point T57, indicating that the subject clock signal CK is normal.

Even after the time point T57, the output signal levels of the registers 41, 44 continue to be confirmed to be inverted at the rise of the subject clock signal CK (at the even-numbered time points), and the output signal levels of the registers 41, 44 continue to be confirmed to be the same (the hold signal levels of the registers 41, 44 are different from each other) at the fall of the subject clock signal CK (at the odd-numbered time points). In the example illustrated in FIG. 5, where the subject clock signal CK has no error cycle, the error detection flag signal output from the register 48 is always at the low level, indicating that the subject clock signal CK is normal.

Next, in the example of the subject clock signal CK illustrated in FIG. 6, which exhibits the long cycle error, there are time points T71 to T84. The odd-numbered time points T71, T73, and so on of the time points T71 to T84 are the falling timings, and the even-numbered time points T72, T74, and so on are the rising timings. The subject clock signal CK is at the low level at the time point T71, and the subject clock signal CK is at the high level at the time point T72, and this repeats at the time points T73 to T84.

The register 41 holds and outputs the levels of the input terminal (the output signal levels of the AND circuit 49) at the rise of the subject clock signal CK at the time points T72, T74, and so on. The register 44 holds and outputs the levels of the input terminal (the output signal levels of the AND circuit 51) at the rise of the subject clock signal CK at the time points T72, T74, and so on. The register 48 holds and outputs the levels of the input terminal (the output signal level of the AND circuit 52) at the fall of the subject clock signal CK at the time points T71, T73, and so on.

As illustrated in FIG. 6, when the reset signal RS changes from the low level to the high level between the time points T74 and T75, the reset signal RS is at the low level at the time points T71, T72, and T73 therebefore. Thus, the output signal level of the AND circuit 52 is at the low level, and the output signal level of the register 48 is at the low level at the time point T71. The error detection flag signal, which is the low level output signal of the register 48, indicates that the subject clock signal CK is normal.

Since the reset signal RS is at the low level at the time point T72, the output signal of the AND circuit 49 is at the low level. This low level causes the output signal of the register 41 to become at the low level at the time point T72. Also, since the output signal of the AND circuit 51 is at the low level at the time point T72, this low level causes the output signal of the register 44 to become at the low level.

As mentioned above, since the reset signal RS is at the low level at the time point T73, the output signal level of the AND circuit 52 is at the low level similarly to the case of the time point T71, and the output signal level of the register 48 is at the low level at the time point T73. The error detection flag signal, which is the low level output signal of the register 48, indicates that the subject clock signal CK is normal.

Since the reset signal RS is at the low level at the time point T74, the output signal of the AND circuit 49 is at the low level similarly to the case of the time point T72. This low level causes the output signal of the register 41 to continue to be the low level at the time point T74. Also, since the output signal of the AND circuit 51 is the low level at the time point T74, this low level causes the output signal of the register 44 to become at the low level.

Since the reset signal RS becomes at the high level at the time point T75, the clock error detection circuit 40, which was in the reset state, starts the clock error detection operation, and the low level output signal level of the register 41 is supplied to the delay circuit 43 via the OR circuit 50. In addition, an exclusive OR of the low level output signal of the register 41 and the low level output signal of the register 44 is taken by the XOR circuit 45. Since the XOR circuit 45 generates the low level output signal, and the low level output signal from the OR circuit 47 is supplied to the AND circuit 52, the AND circuit 52 maintains the low level output signal. The error detection flag signal, which is the output signal of the register 48, is maintained at the low level at the time point T75, indicating that the subject clock signal CK is normal. In other words, the error detection flag signal having the high level is not generated.

At the rising timing of the subject clock signal CK after the time point T76, the level held until then in the register 41 is inverted by the inverter 42, and the inverted level is held and output by the register 41 at the next rising timing. The output signal of the register 41 switches between the high level and the low level at each rising timing of the subject clock signal CK.

At the time point T76, since the high level output signal of the register 41 is supplied to the delay circuit 43 via the OR circuit 50 without change, the high level output signal of the register 41 is delayed by the delay circuit 43 for the time of slightly longer than the one prescribed cycle TCK of the subject clock signal CK, and the delayed signal is input to the input terminal of the register 44 via the AND circuit 51. Since the delay time of the delay circuit 43 is the time of slightly longer than the one prescribed cycle TCK of the subject clock signal CK, the high level output signal of the AND circuit 51 is held and output to the register 44 at the time point T76.

At the time point T77, unlike at the time point T75, the high level output signal from the register 41 and the high level output signal from the register 44 are input into the XOR circuit 45. However, since the XOR circuit 45 continuously generates the low level output signal without change, the low level output signal is supplied from the OR circuit 47 to the AND circuit 52 similarly to the time point T75. Thus, the AND circuit 52 maintains the low level output signal. The output signal of the register 48 is maintained at the low level at the time point T77, indicating that the subject clock signal CK is normal.

At the time point T78, since the low level output signal of the register 41 is supplied to the delay circuit 43 via the OR circuit 50 without change, the low level output signal of the register 41 is delayed by the delay circuit 43 for a time of slightly longer than the one prescribed cycle TCK of the subject clock signal CK, and the delayed signal is input to the input terminal of the register 44 via the AND circuit 51. Since the delay time of the delay circuit 43 is the time of slightly longer than the one prescribed cycle TCK of the subject clock signal CK, the low level output signal of the AND circuit 51 is held and output to the register 44 at the time point T78.

As illustrated in FIG. 6, the period from the time point T78 to a time point T80 is an error clock period of a long cycle in the subject clock signal CK, and it is longer than the one prescribed cycle TCK in the period.

At the time point T79 in the long cycle error clock period, unlike at the time point T77, the low level output signal of the register 41 and the low level output signal of the register 44 are input to the XOR circuit 45. However, the XOR circuit 45 generates the low level output signal without change, the low level output signal is supplied from the OR circuit 47 to the AND circuit 52 as before, and the AND circuit 52 maintains the low level output signal. The output signal of the register 48 continues to be maintained at the low level at the time point T79, indicating that the subject clock signal CK is normal.

At the time point T80 when the long cycle error clock period ends, the delay time of the delay circuit 43 from the time point T78 has already ended, and the output signal level of the delay circuit 43 is at the low level. Since the low level is supplied to the register 44 via the AND circuit 51, the register 44 maintains the low level output signal at the time point T80. Thus, the low level output signal is supplied to one input terminal of the XOR circuit 45. The register 41 generates the high level output signal at the time point T80, and this high level output signal is supplied to the delay circuit 43 via the OR circuit 50 without change while the high level output signal from the register 41 is input to the other input terminal of the XOR circuit 45. Therefore, the XOR circuit 45 takes an exclusive OR of the high level output signal of the register 41 and the low level output signal of the register 44. As illustrated in FIG. 6, since the XOR circuit 45 generates the high level output signal instead of the low level output signal at the time point T80, the high level output signal from the OR circuit 47 is supplied to the AND circuit 52. As a result, the output signal of the AND circuit 52 changes from the low level to the high level. Since this high level is held in the register 48 at the time point T81, the error detection flag signal, which is the output signal of the register 48, changes from the low level to the high level at the time point T81, indicating an error in the subject clock signal CK.

After the time point T80, the cycle of the subject clock signal CK returns to the prescribed cycle TCK and becomes normal. As a result, since the output signal level of the register 41 and the output signal level of the register 44 match after a time point T82, the output signal of the XOR circuit 45 return to the low level. However, since the high level output signal of the register 48 is supplied to the AND circuit 52 via the OR circuit 47, the AND circuit 52 maintain the high level output signal. Thus, since the high level is held by the register 48 at the odd-numbered time points T83, and so on, the error detection flag signal, which is the output signal of the register 48, maintains the high level, and indicates the error in the subject clock signal CK.

Accordingly, in the clock error detection circuit 40 of Embodiment 2, the cycle signal that reverses its level at each rising timing of the subject clock signal CK is generated by the frequency dividing circuit including the register 41, the delay circuit 43 delays the cycle signal by the time of slightly longer than the one prescribed cycle TCK of the subject clock signal CK to generate the delayed signal, the level of the delayed signal is held in the register 44 at each rising timing of the subject clock signal CK to generate the hold signal, the XOR circuit 45 determines whether the level of the cycle signal matches the level of the hold signal, and when the XOR circuit 45 does not obtain a determination result of the match, the high level error detection flag signal indicating the error in the subject clock signal CK is generated. Thus, the long cycle error in which the cycle of the subject clock signal CK becomes longer than the prescribed cycle TCK can be detected with a simple configuration and with a high detection accuracy.

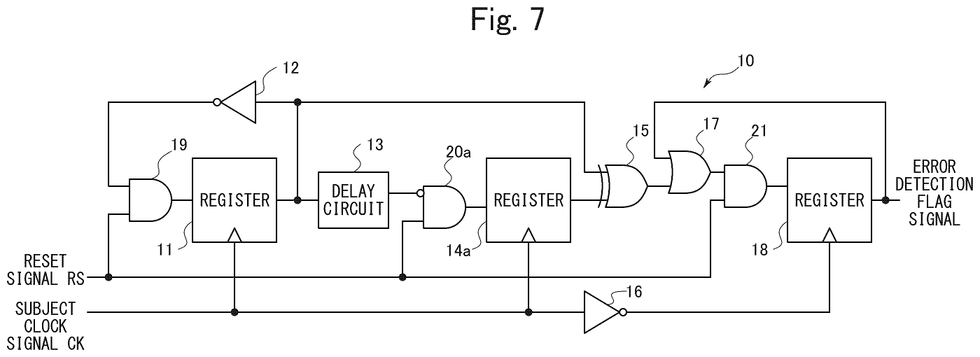

Furthermore, the specific circuit configurations of the clock error detection circuit 10 of Embodiment 1 and the clock error detection circuit 40 of Embodiment 2 are not limited to those described above. For example, in the clock error detection circuit 10, an AND circuit 20a can be used instead of the OR circuit 20 as illustrated in FIG. 7. When using the AND circuit 20a, it is not necessary to use a register for outputting an inverted signal as in the case of the register 14, as a register 14a which is connected to an output terminal of the AND circuit 20a. The other configuration is the same as the clock error detection circuit 10 illustrated in FIG. 1.

The clock error detection circuit 10 of Embodiment 1 is configured to detect the short cycle error in which the cycle of the subject clock signal CK becomes shorter than the prescribed cycle TCK. The clock error detection circuit 40 of Embodiment 2 is configured to detect the long cycle error in which the cycle of the subject clock signal CK becomes longer than the prescribed cycle TCK. However, it is also possible to use the clock error detection circuit 10 and the clock error detection circuit 40 as a single clock error detection circuit to detect both the short cycle error and the long cycle error in the subject clock signal CK. In such a clock error detection circuit, a circuit for the short cycle error detection system and the long cycle error detection system can be made common. For example, the frequency dividing circuit, which doubles the cycle of the subject clock signal CK, and the cycle error signal generation circuit, which generates the high level error detection flag signal by holding the high level output of the XOR circuit 15 or 45, can be made common by both the short cycle error detection system and the long cycle error detection system.

In addition, the delay time of the delay circuits 13 in the clock error detection circuit 10 of Embodiment 1 is set to the time of slightly shorter than the one prescribed cycle TCK of the subject clock signal CK in the case of the short cycle error detection and the delay time of the delay circuits 43 in the clock error detection circuit 40 of Embodiment 2 is set to the time of slightly longer than the one prescribed cycle TCK of the subject clock signal CK in the case of the long cycle error detection. However, it is also possible to configure each of the delay circuits 13, 43 such that several types of delay times are allowed to be set selectively from outside.

Also, the delay time of the delay circuit 13 is shorter than the prescribed cycle TCK of the subject clock signal CK. However, the closer the delay time is set to the prescribed cycle TCK, the higher the detection accuracy for the short cycle error can be. Similarly, the delay time of the delay circuit 43 is longer than the prescribed cycle TCK of the subject clock signal CK. However, the closer the delay time is to the prescribed cycle TCK, the higher the detection accuracy for the long cycle error can be.

What is claimed is:

1. A clock error detection circuit for detecting an error in cycle length of a subject clock signal, comprising:
a cycle signal generation circuit that generates a cycle signal that reverses a level thereof at a start of each one cycle of the subject clock signal;
a delay circuit that delays the cycle signal by a time shorter or a time longer than a prescribed cycle for the subject clock signal to output a delayed signal of the cycle signal;
a holding circuit that holds a level of the delayed signal at the start of each one cycle of the subject clock signal to generate a hold signal; and
a determination circuit that determines whether the level of the cycle signal matches the level of the hold signal to generate a result of the determination.

2. The clock error detection circuit according to claim 1, further comprising
a cycle error signal generation circuit that generates and holds a cycle error flag signal indicating an error in the cycle length of the subject clock signal when the determination result indicates that the level of the cycle signal does not match the level of the hold signal.

3. The clock error detection circuit according to claim 1, wherein
the cycle signal generation circuit includes a frequency dividing circuit that divides the subject clock signal by two.

4. The clock error detection circuit of claim 1, wherein
the determination circuit includes an XOR circuit that takes an exclusive OR of the level of the cycle signal and the level of the hold signal.

5. A clock error detection circuit for detecting an error in cycle length of a subject clock signal, comprising:
a cycle signal generation circuit that generates a cycle signal that reverses a level thereof at a start of each one cycle of the subject clock signal;
a first delay circuit that delays the cycle signal by a time shorter than a prescribed cycle for the subject clock signal to output a first delayed signal of the cycle signal;
a second delay circuit that delays the cycle signal by a time longer than a prescribed cycle for the subject clock signal to output a second delayed signal of the cycle signal;
a holding circuit that at the start of each one cycle of the subject clock signal, holds a level of the first delayed signal to generate a first hold signal and holds a level of the second delayed signal to generate a second hold signal;
a first determination circuit that determines whether the level of the cycle signal matches the level of the first hold signal to generate a result of the determination; and
a second determination circuit that determines whether the level of the cycle signal matches the level of the second hold signal to generate a result of the determination.
